(19) United States
(12) Patent Application Publication
(10) Pub. No.: US 2009/0193313 A1
(43) Pub. Date: Jul. 30, 2009

(54) Method and apparatus for decoding concatenated code

(75) Inventors: Jun Jin Kong, Yongin-si (KR); Jae Hong Kim, Seoul (KR); Yong June Kim, Seoul (KR); Young Hwan Lee, Suwon-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/149,999

(22) Filed: May 12, 2008

(30) Foreign Application Priority Data
Jan. 30, 2008 (KR) 10-2008-0009752

(51) Int. Cl. H03M 13/00

(52) U.S. Cl. 714/755

(57) ABSTRACT

Provided are apparatuses for decoding a concatenated code and methods for the same that may improve the decoding speed of a concatenated code based on a likelihood value with respect to output from a plurality of decoders.

A method of decoding a concatenated code may include: calculating a likelihood value of concatenated encoded received data; performing first decoding for the received data based on the calculated likelihood value to generate first decoded data; performing second decoding for the first decoded data to generate second decoded data; and determining whether to perform iterative decoding based on the second decoded data.

According to example embodiments, it is possible to directly manage the quality of concatenated decoded data to thereby accurately determine whether to perform iterative decoding for concatenated encoded data. Also, it may be possible to quickly decode concatenated encoded received data.

### PRIORITY STATEMENT

This application claims priority under 35 U.S.C. §119 to Korean Patent Application No. 10-2008-0009752, filed on Jan. 30, 2008, in the Korean Intellectual Property Office (KIPO), the entire contents of which are incorporated herein by reference.

### BACKGROUND

1. Field

Example embodiments relate to decoding of a concatenated code, and more particularly, to apparatuses and methods that may improve the decoding speed of a concatenated code based on a likelihood value with respect to output from a plurality of decoders.

2. Description of Related Art

In the conventional field of wireless communication, for example mobile communication and the like, a relatively large number of errors may occur due to channel noise caused by fading and the like. The fading may occur due to propagation delay of a signal and receiving of a signal via multiple propagation paths. Error correction codes (ECC) may be used to solve the above-described problems and improve the data reliability. The ECC may be an important factor in a digital mobile communication system.

Generally, in the field of wireless communication, for example mobile communication and the like, due to complex phenomena, for example, noise and interference that may occur in wireless channels, a relatively large number of errors may occur in comparison to wired communication. A concatenated code used as ECC may have strong error correcting capability by using two different ECC. When sufficiently performing iterative decoding for the concatenated encoded data, it may be possible to obtain the excellent performance that is near to Shannon's Limit in an aspect of a bit error rate (BER).

However, the conventional scheme may cause many problems, for example an increase in complexity due to a large amount of calculations, decoding delay due to interleaver and iterative decoding, and real-time processing. Under this situation, as a number of iterative decodings increases, the BER may be improved, whereas there may be a limit on the delay time of data transmission. In the case of a concatenated code decode, although the number of iterative decodings may increase, coding gain may no longer be improved.

The increase in the number of iterative decodings for the performance improvement of the BER may increase the decoding time. Accordingly, the actual system may not constantly increase the number of iterative decodings in order to obtain improved BER performance. Accordingly, iterative decoding technology may be ineffective in a concatenated code decoder with a predetermined level of performance and may delay data decoding.

### SUMMARY

Example embodiments, may provide a method of decoding a concatenated code the method including: calculating a likelihood value of concatenated encoded received data; performing first decoding for the received data based on the calculated likelihood value to generate first decoded data; performing second decoding for the first decoded data to generate second decoded data; and determining whether to perform iterative decoding based on the second decoded data.

Example embodiments may provide a method of decoding a concatenated code, the method including: performing first decoding for concatenated encoded received data to generate first decoded data; separating the first decoded data into a plurality of sub-data blocks; and performing second decoding for each of the separated plurality of sub-data blocks to generate a plurality of second decoded data.

Example embodiments may provide an apparatus for decoding a concatenated code. The concatenated code decoding apparatus may include: an likelihood value calculator configured to calculate a likelihood value of concatenated encoded received data; a first decoding unit configured to perform first decoding for the received data based on the calculated likelihood value to generate first decoded data; a second decoding unit configured to perform second decoding for the first decoded data to generate second decoded data; and a decoding determination unit configured to determine whether to perform iterative decoding based on the second decoded data.

Example embodiments may provide an apparatus for decoding a concatenated code. The concatenated code decoding apparatus may include: a first decoding unit configured to perform first decoding for concatenated encoded received data to generate first decoded data; a data separator configured to separate the first decoded data into a plurality of sub-data blocks; and a second decoding unit configured to perform second decoding for each of the separated plurality of sub-data blocks to generate a plurality of second decoded data.

According to example embodiments, it may be possible to directly manage the quality of concatenated decoded data to thereby accurately determine whether to perform iterative decoding for concatenated encoded data. Also, it is possible to quickly decode concatenated encoded received data.

### BRIEF DESCRIPTION OF THE DRAWINGS

The above and other features and advantages of example embodiments will become more apparent by describing in detail example embodiments with reference to the attached drawings. The accompanying drawings are intended to depict example embodiments and should not be interpreted to limit the intended scope of the claims. The accompanying drawings are not to be considered as drawn to scale unless explicitly noted.

FIG. 1 is a flowchart illustrating a method of decoding a concatenated code according to example embodiments.

FIG. 2 is a flowchart illustrating a concatenated code decoding method of determining whether to perform iterative decoding based on second decoded data according to example embodiments.

FIG. 3 is a flowchart illustrating a concatenated code decoding method of separating first decoded data into a plurality of sub-data blocks according to example embodiments.

FIG. 4 is a block diagram illustrating the structure of a concatenated code decoding apparatus according to example embodiments.

FIG. 5 is a block diagram illustrating the structure of a concatenated code decoding apparatus using a plurality of decoders according to example embodiments.

FIG. 6 illustrates an example of separating first decoded data into a plurality of sub-data blocks according to example embodiments.

FIG. 7 is a block diagram illustrating the structure of a concatenated code decoding apparatus to determine whether to perform iterative decoding based on output from a plurality of decoders according to example embodiments.

FIG. 8 illustrates an example of performing iterative decoding for received data to thereby reduce errors in a plurality of second decoded data according to example embodiments.

### DESCRIPTION OF EXAMPLE EMBODIMENTS

Detailed example embodiments are disclosed herein. However, specific structural and functional details disclosed herein are merely representative for purposes of describing example embodiments. Example embodiments may, however, be embodied in many alternate forms and should not be construed as limited to only the embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but to the contrary, example embodiments are to cover all modifications, equivalents, and alternatives falling within the scope of example embodiments. Like numbers refer to like elements throughout the description of the figures.

It will be understood that when an element is referred to as being “on,” “connected to,” “electrically connected to,” or “coupled to” to another component, it may be directly on, connected to, electrically connected to, or coupled to the other component or intervening components may be present. In contrast, when a component is referred to as being “directly on,” “directly connected to,” “directly electrically connected to,” or “directly coupled to” another component, there are no intervening components present. As used herein, the term “and/or” includes any and all combinations of one or more of the associated listed items.

It will be understood that although the terms first, second, third, etc., may be used herein to describe various elements, components, regions, layers, and/or sections, these elements, components, regions, layers, and/or sections should not be limited by these terms. These terms are only used to distinguish one element, component, region, layer, and/or section from another element, component, region, layer, and/or section. For example, a first element, component, region, layer, and/or section could be termed a second element, component, region, layer, and/or section without departing from the teachings of example embodiments.

Spatially relative terms, such as “beneath,” “below,” “lower,” “above,” “upper,” and the like may be used herein for ease of description to describe the relationship of one component and/or feature to another component and/or feature, or other component(s) and/or feature(s), as illustrated in the drawings. It will be understood that the spatially relative terms are intended to encompass different orientations of the device in use or operation in addition to the orientation depicted in the figures.

The terminology used herein is for the purpose of describing particular example embodiments only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used in this specification, specify the presence of stated features, integers, steps, operations, elements, and/or components, but do not preclude the presence or addition of one or more other features, integers, steps, operations, elements, and/or components.

Unless otherwise defined, all terms (including technical and scientific terms) used herein have the same meaning as commonly understood by one of ordinary skill in the art to which example embodiments belongs. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Reference will now be made to example embodiments, which are illustrated in the accompanying drawings, wherein like reference numerals may refer to like components throughout.

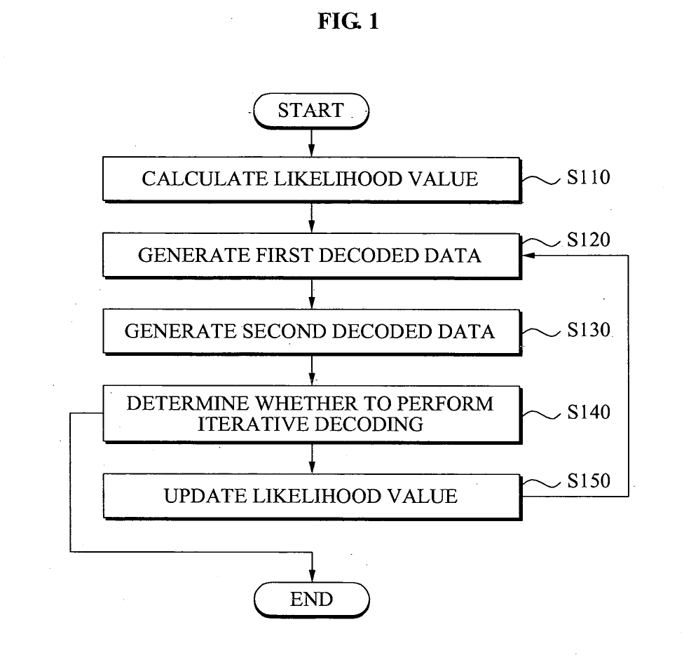

FIG. 1 is a flowchart illustrating a method of decoding a concatenated code according to example embodiments. Hereinafter, the concatenated code decoding method will be described in detail with reference to FIG. 1.

In operation S110, a likelihood value of concatenated encoded received data may be calculated. According to example embodiments, the likelihood value calculated in operation S110 may include at least one of a likelihood ratio, a log likelihood ratio (LLR), a probability value, and a posteriori probability. Hereinafter, an example of calculating the LLR to perform concatenated code decoding in operation S110 will be described. Even when the likelihood ratio, the probability value, and the posteriori probability are calculated in operation S110, example embodiments of the invention may be applicable using a similar scheme. According to example embodiments, the received data may pass through a channel and thereby be received. While passing through the channel, an error may occur in the data. The likelihood value may be associated with the error that occurs in the received data.

According to example embodiments, the channel in operation S110 may be a channel between a transmitter and a receiver in a communication system for transmitting data. The channel between the transmitter and the receiver may include both a wired channel and a wireless channel. In the case of the wireless channel, an error may occur in data received via the wireless channel due to an interference signal and noise. The transmitter may encode data according to a concatenated encoding scheme. The receiver may decode the encoded data according to a concatenated decoding scheme to thereby eliminate the error in the data.

According to example embodiments, the channel in operation S110 may be a channel between a memory that stores data and a data processing apparatus. The data processing apparatus may receive the stored data and perform concatenated code decoding to thereby eliminate the error in the data.

In operation S120, a first decoding for the received data may be performed based on the calculated likelihood value to generate first decoded data. According to example embodiments, the received data may be encoded according to a convolutional encoding scheme. The first decoded data may be generated by performing first decoding according to a convolutional decoding scheme, for example a Viterbi decoding scheme and the like. According to other example embodiments, the received data may be encoded according to a turbo encoding scheme. The first decoded data may be generated by performing first decoding according to a turbo decoding scheme. According to still other example embodiments, the received data may be encoded according to a Low-Density Parity-Check (LDPC) codes encoding scheme. The first decoded data may be generated by performing first decoding according to an LDPC decoding scheme. In the case of the turbo decoding scheme and the LDPC decoding scheme, the decoding capability may be improved in proportion to the number of iterative decodings and thereby an error may be reduced in the decoded data. Accordingly, the turbo decoding scheme and the LDPC decoding scheme may be classified as an iterative decoding scheme. According to yet other example embodiments, the received data may be encoded according to a Trellis-Coded Modulation (TCM) encoding scheme or a Block-Coded Modulation (BCM) encoding scheme. The first decoded data may be generated by performing first decoding according to a TCM decoding scheme or a BCM decoding scheme.

In operation S130, a second decoding for the first decoded data may be performed to generate second decoded data. According to example embodiments, the first decoded data may be encoded according to the convolutional encoding scheme, the TCM encoding scheme, the BCM encoding scheme, a Reed-Solomon (RS) encoding scheme, or a Bose-Chadhuri-Hocquenghem (BCH) encoding scheme. The second decoded data that may be generated by performing second decoding according to a decoding scheme corresponding to at least one of the above encoding schemes.

In operation S140, it may determine whether to perform iterative decoding for the received data based on the second decoded data.

According to example embodiments, in operation S140, it is possible to determine whether to perform iterative decoding for the received data based on an error rate, a number of iterative decodings, and an likelihood value of the second decoded data.

According to example embodiments, in operation S140, it is possible to calculate the likelihood value of the second decoded data based on the second decoded data that is decoded in operations S120 and S130. The likelihood value of the second decoded data calculated in operation S140 may be compared with a predetermined threshold ratio. When the calculated likelihood value is less than the threshold ratio, it may be determined to perform iterative decoding for the received data. According to other example embodiments, it is possible to calculate a stopping criteria of an iterative decoder based on the calculated likelihood value to thereby determine whether to stop performing iterative decoding.

When it is determined to not perform iterative decoding for the received data in operation S140, the decoding procedure of the concatenated code may be terminated.

Conversely, when it is determined to perform iterative decoding for the received data in operation S140, the likelihood value may be updated based on the second decoded data in operation S150. Also, in operation S120, first decoding of the received data may be performed based on the updated likelihood value and first decoded data may be regenerated.

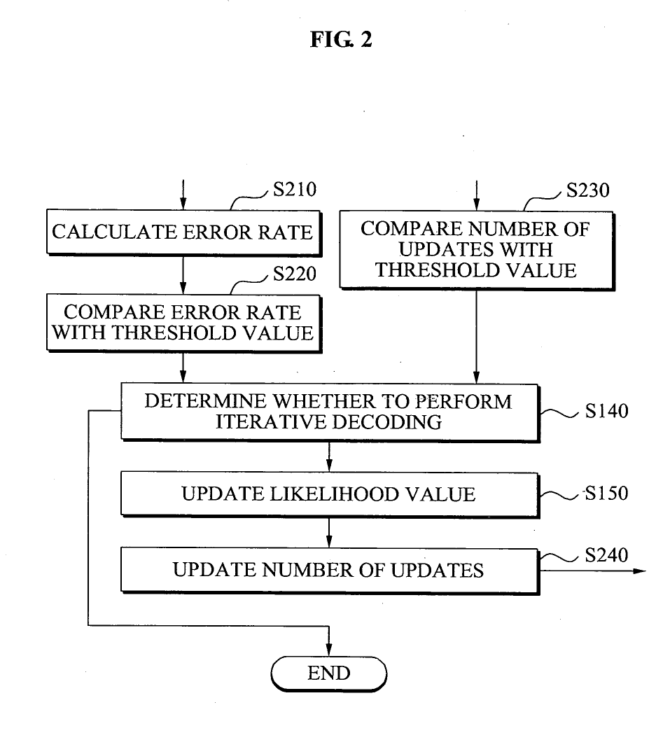

FIG. 2 is a flowchart illustrating a concatenated code decoding method which includes determining whether to perform iterative decoding based on second decoded data according to example embodiments. Hereinafter, the concatenated code decoding method will be described in detail with reference to FIG. 2.

In operation S210, an error rate of the second decoded data may be calculated.

In operation S220, the calculated error rate may be compared with a predetermined threshold rate.

In operation S140, it may be determined whether to perform iterative decoding for the received data based on the comparison result. According to example embodiments, when the calculated error rate is less than the threshold rate, it may be determined to not perform iterative decoding. Conversely, when the calculated error rate is greater than or equal to the threshold rate, it may be determined to perform iterative decoding.

According to example embodiments, since the likelihood value may be updated in operation S150, the number of updates for the likelihood value may be updated in operation S240. In operation S230, the method may compare the number of updates for the likelihood value with a predetermined threshold number.

According to example embodiments, when the number of updates for the likelihood value is less than the threshold number, it may be determined to perform iterative decoding for the received data. Conversely, when the number of updates is greater than or equal to the threshold number, it may be determined to not perform iterative decoding for the received data.

According to example embodiments, the method may further include an operation of updating the number of updates for the likelihood value and an operation of comparing the updated number of updates with the threshold number. According to other example embodiments, when the number of updates for the likelihood value is less than the threshold ratio, it may be determined to perform iterative decoding for received data.

According to example embodiments, whether to perform iterative decoding for a concatenated code may be determined based on second decoded data that is the final output according to the concatenated code decoding scheme. Accordingly, it may be possible to more directly manage the quality of decoded data to thereby more accurately determine whether to perform iterative decoding.

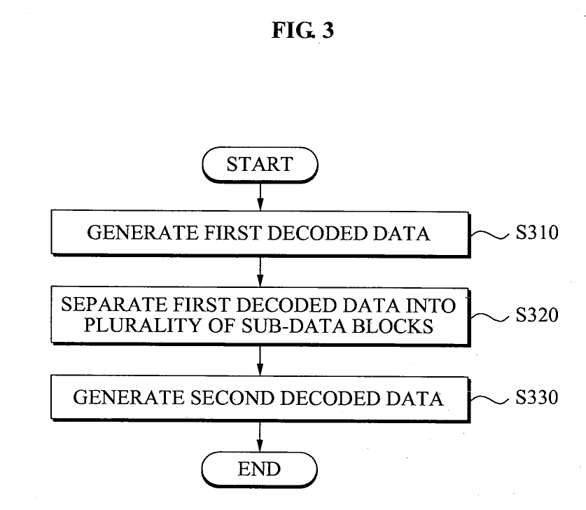

FIG. 3 is a flowchart illustrating a concatenated code decoding method of separating first decoded data into a plurality of sub-data blocks according to example embodiments. Hereinafter, the concatenated code decoding method will be described in detail with reference to FIG. 3.

In operation S310, first decoding for concatenated encoded received data may be performed to generate first decoded data. According to example embodiments, the received data may be encoded according to a convolutional encoding scheme, a turbo encoding scheme, a TCM encoding scheme, a BCM encoding scheme, or an LDPC encoding scheme. In operation S310, the method may decode the received data according to a Viterbi decoding scheme, a turbo decoding scheme, a TCM decoding scheme, a BCM decoding scheme, or an LDPC decoding scheme corresponding to the above encoding scheme.

In operation S320, first decoded data may be separated into a plurality of sub-data blocks. According to example embodiments, all the sub-data blocks may have the same length and may also have the different length.

In operation S330, second decoding may be performed for each of the separated sub-data blocks to generate a plurality of second decoded data. According to example embodiments, second decoded data for each of the sub-data blocks may be generated by performing second decoding according to at least one of the Viterbi decoding scheme, the turbo decoding scheme, the TCM decoding scheme, the BCM decoding scheme, the LDPC decoding scheme, a Hamming decoding scheme, an RS decoding scheme, and a BCH decoding scheme.

According to example embodiments, all the separated sub-data blocks may be encoded according to the same encoding scheme. In this case, in operation S330, the sub-data blocks may be decoded according to the same decoding scheme corresponding to the above encoding scheme.

According to other example embodiments, each of the separated sub-data blocks may be encoded according to a different encoding scheme. In this case, in operation S330, each of the separated sub-data blocks may be decoded according to a decoding scheme corresponding to the above encoding scheme.

As described above, the second decoded data may be generated by separating the first decoded data into the plurality of sub-data blocks and performing second decoding for each of the separated sub-data blocks. According to example embodiments, the method may perform second decoding for the plurality of separated sub-data blocks with the relatively short length, instead of performing second decoding for the first decoded data with the relatively long length. Since the second decoding may be performed in parallel, the second decoding time may be reduced. It is possible to quickly decode the concatenated encoded received data.

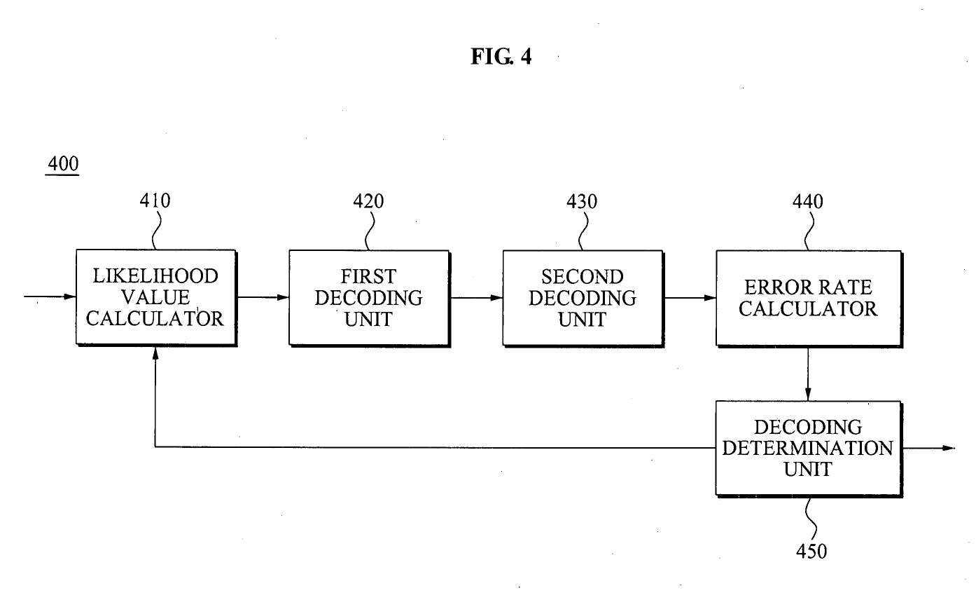

FIG. 4 is a block diagram illustrating the structure of a concatenated code decoding apparatus 400 according to example embodiments. Hereinafter, the operation of the concatenated code decoding apparatus 400 will be described in detail with reference to FIG. 4. The concatenated code decoding apparatus 400 may include an likelihood value calculator 410, a first decoding unit 420, a second decoding unit 430, an error rate calculator 440, and a decoding determination unit 450.

The likelihood value calculator 410 may calculate an likelihood value of concatenated encoded received data. According to example embodiments, the received data may pass through a channel and thereby be received. The channel may be a channel between a transmitter and a receiver in a communication system for transmitting data. Also, the channel may be a channel between a memory that stores data and a data processing apparatus. While passing through the channel, an error may occur in the data. The concatenated code decoding apparatus 400 may eliminate the error in the received data.

The first decoding unit 420 may perform first decoding for the received data based on the calculated likelihood value to generate first decoded data. According to example embodiments, the received data may be encoded according to a convolutional encoding scheme, a turbo encoding scheme, a TCM encoding scheme, a BCM encoding scheme, or an LDPC encoding scheme. The first decoding unit 420 may decode the received data according to a Viterbi decoding scheme, a turbo decoding scheme, a TCM decoding scheme, a BCM decoding scheme, or an LDPC decoding scheme corresponding to the above encoding scheme.

In the case of the turbo decoding scheme and the LDPC decoding scheme the decoding capability may be improved in proportion to the number of iterative decodings and thereby an error may be reduced in the decoded data. Accordingly, the turbo decoding scheme and the LDPC decoding scheme may be classified into an iterative decoding scheme.

The second decoding unit 430 may perform second decoding for the first decoded data to generate second decoded data. According to example embodiments, the first decoded data may be encoded according to any one of the convolutional encoding scheme, the turbo encoding scheme, the TCM encoding scheme, the BCM encoding scheme, the LDPC encoding scheme, a Hamming encoding scheme, an RS encoding scheme, and a BCH encoding scheme. The second decoding unit 430 may perform decoding according to a decoding scheme corresponding to the above encoding scheme of the first decoded data.

The error rate calculator 440 may determine whether the error occurs in the second decoded data or may calculate an error rate of the second decoded data. The error rate may be defined by the length of data that includes the error with respect to the length of all data included in the second decoded data.

The decoding determination unit 450 may determine whether to perform iterative decoding for received data, based on whether the error occurs in the second decoded data, or the error rate of the second decoded data. According to example embodiments, the decoding determination unit 450 may determine the likelihood value of the second decoded data and determine whether to perform iterative decoding based on the calculated likelihood value. According to example embodiments, the likelihood value calculated by the decoding determination unit 450 may include at least one of a likelihood ratio, an LLR, a probability value, and a posteriori probability. The decoding determination unit 450 may compare the likelihood value of the second decoded data with a predetermined threshold ratio. When the likelihood value of the second decoded data is greater than or equal to the threshold ratio, the decoding determination unit 450 may determine to not perform iterative decoding for the received data. Conversely, when the likelihood value of the second decoded data is less than the threshold ratio, the decoding determination unit 450 may determine to perform iterative decoding for the received data. Also, it is possible to calculate stopping criteria of an iterative decoder based on the calculated likelihood value to thereby determine whether to perform iterative decoding.

According to example embodiments, when the decoding determination unit 450 determines to perform iterative decoding, the likelihood value calculator 410 may calculate the likelihood value of the second decoded data and update the likelihood value of the received signal. The first decoding unit 420 may perform first decoding for the received data based on the updated likelihood value and regenerate the first decoded data.

According to example embodiments, the likelihood value calculator 410 may update the number of likelihood value updates when the likelihood value is updated. The decoding determination unit 450 may determine whether to perform iterative decoding for the received data based on the comparison result regarding the number of updates. According to example embodiments, the decoding determination unit 450 may compare the number of updates for the likelihood value with a predetermined threshold ratio. When the number of updates for the likelihood value is less than the threshold ratio, the decoding determination unit 450 may determine to perform iterative decoding for the received data. Conversely, when the number of updates for the likelihood value is greater than or equal to the threshold number, the decoding determination unit 450 may determine to not perform iterative decoding for the received data.

According to example embodiments, the error rate calculator 440 may calculate the error rate of the second decoded data. The decoding determination unit 450 may compare the calculated error rate with the threshold rate and determine whether to perform iterative decoding for the received data based on the comparison result. For example, when the calculated error rate is less than a predetermined threshold rate, the decoding determination unit 450 may determine to not perform iterative decoding for the received data. When the calculated error rate is greater than the threshold rate, the decoding determination unit 450 may determine to perform iterative decoding for the received data.

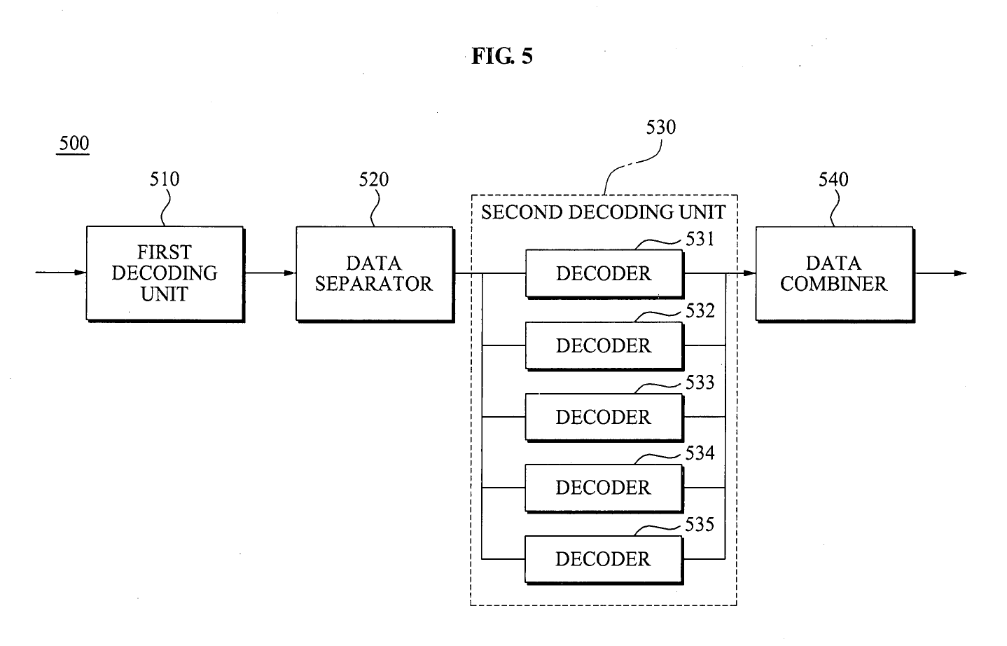

FIG. 5 is a block diagram illustrating the structure of a concatenated code decoding apparatus 500 using a plurality of decoders according to example embodiments. Hereinafter, the operation of the concatenated code decoding apparatus 500 will be described in detail with reference to FIG. 5. The concatenated code decoding apparatus 500 may include a first decoding unit 510, a data separator 520, a second decoding unit 530, and a data combiner 540.

The first decoding unit 510 may perform first decoding for concatenated encoded received data to generate first decoded data. According to example embodiments, the received data may be encoded according to a convolutional encoding scheme, a turbo encoding scheme, a TCM scheme, a BCM encoding scheme, or an LDPC encoding scheme. The first decoding unit 510 may perform first decoding according to a decoding scheme corresponding to the above encoding scheme of the received data, that is, according to a Viterbi decoding scheme, a turbo decoding scheme, a TCM decoding scheme, a BCM decoding scheme, or an LDPC decoding scheme.

The data separator 520 may separate the first decoded data into a plurality of sub-data blocks. According to example embodiments, the data separator 520 may separate the first decoded data into a plurality of sub-data blocks with the same length and may also separate the first decoded data into the plurality of sub-data blocks with the different length.

The second decoding unit 530 may perform second decoding for each of the separated sub-data blocks to generate a plurality of second decoded data. According to example embodiments, the second decoding unit 530 may include a plurality of decoders 531, 532, 533, 534, and 535 that may perform second decoding for the plurality of separated sub-data blocks.

The second decoding unit 530 may decode sub-data blocks with the relatively short length, instead of decoding first decoded data with the relatively long length. When decoding the sub-data blocks in parallel using the plurality of decoders 531, 532, 533, 534, and 535, it is possible to reduce the decoding time.

According to example embodiments, each of the sub-data blocks may be encoded according to one or more of the convolutional encoding scheme, the turbo encoding scheme, the TCM encoding scheme, the BCM encoding scheme, the LDPC encoding scheme, a Hamming encoding scheme, an RS encoding scheme, and the BCH encoding scheme. The second decoding unit 530 may perform second decoding according to a decoding scheme corresponding to the above encoding scheme of each of the sub-data blocks, that is, according to at least one of the Viterbi decoding scheme, the turbo decoding scheme, the TCM decoding scheme, the BCM decoding scheme, the LDPC decoding scheme, a Hamming decoding scheme, an RS decoding scheme, and the BCH decoding scheme.

The data combiner 540 may combine a plurality of second decoded data, generated by the decoders 531, 532, 533, 534, and 535, to thereby generate a decoded data stream.

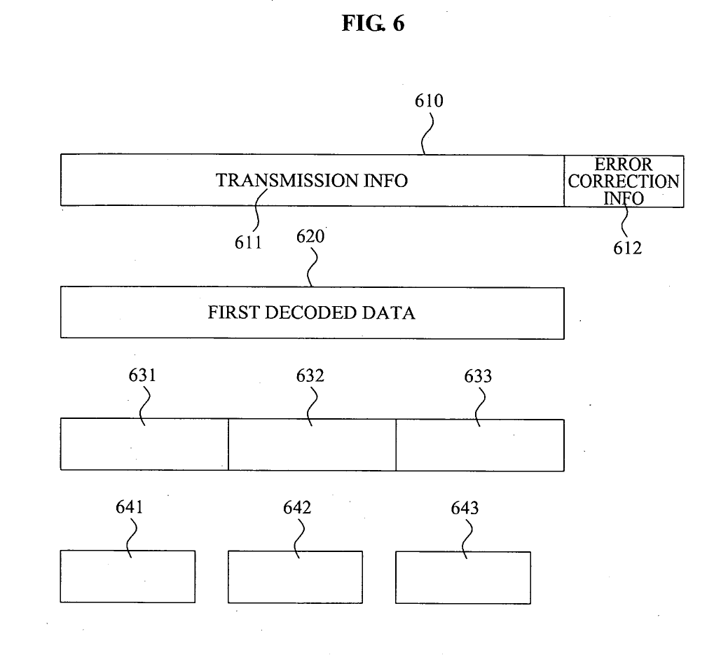

FIG. 6 illustrates an example of separating first decoded data into a plurality of sub-data blocks according to example embodiments. Hereinafter, separating of the first decoded data will be described in detail with reference to FIG. 6.

The first decoding unit 510 of the concatenated code decoding apparatus 500 shown in FIG. 5 may decode received data 610 to generate first decoded data 620. The received data 610 may include transmission information 611 and error correction information 612. The transmission information 611 may include an error that occurs while passing through a channel.

The first decoding unit 510 may perform first decoding for the received data 610 to generate the first decoded data 620. The first decoding unit 510 may correct the error included in the transmission information 611 by referring to the error correction information 612 to thereby generate the first decoded data 620.

The data separator 520 may separate the first decoded data 620 to thereby generate a plurality of sub-data blocks 631, 632, and 633. In FIG. 6, the sub-data blocks 631, 632, and 633 have the same length. According to example embodiments, each of the sub-data blocks 631, 632, and 633 may have a different length.

The second decoding unit 530 may decode each of the sub-data blocks 631, 632, and 633 to thereby generate a plurality of second decoded data 641, 642, and 643. According to example embodiments, each of the sub-data blocks 631, 632, and 633 may include transmission data and error correction information. The second decoding unit 530 may generate the plurality of decoded data 641, 642, and 643 from the transmission data based on the error correction information that is included in the sub-data blocks 631, 632, and 633.

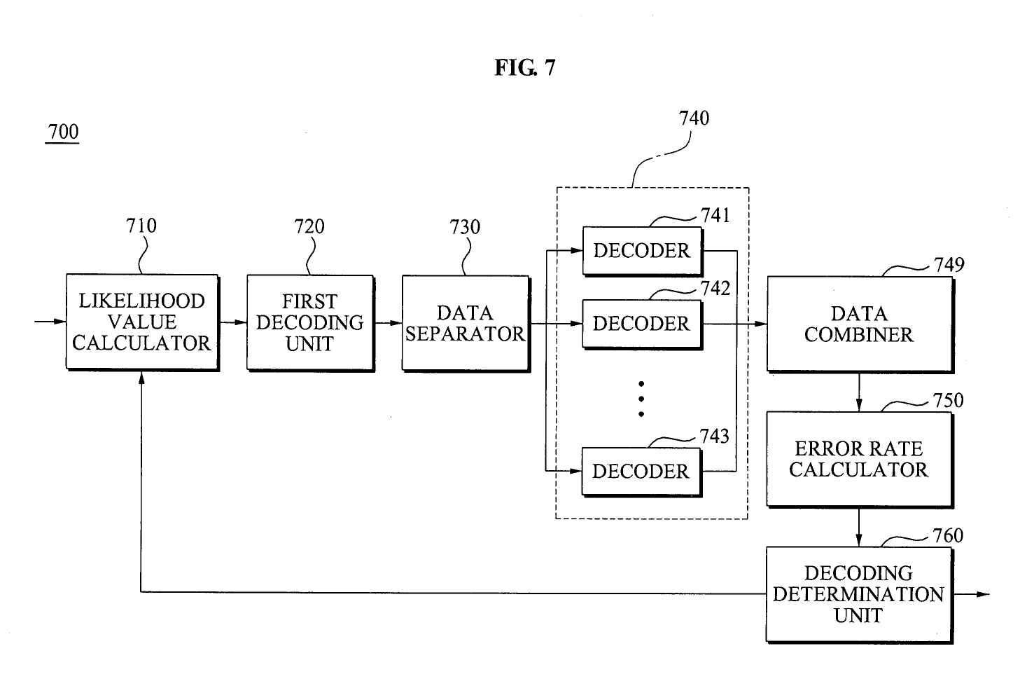

FIG. 7 is a block diagram illustrating the structure of a concatenated code decoding apparatus 700 to determine whether to perform iterative decoding based on output from a plurality of decoders according to example embodiments. Hereinafter, the operation of the concatenated code decoding apparatus 700 will be described in detail with reference to FIG. 7. The concatenated code decoding apparatus 700 may include a likelihood value calculator 710, a first decoding unit 720, a data separator 730, a second decoding unit 740, a data combiner 749, an error rate calculator 750, and a decoding determination unit 760.

The likelihood value calculator 710 may calculate a likelihood value of concatenated encoded received data. According to example embodiments, the likelihood value may include at leas tone of a likelihood ratio, an LLR, a probability value, and a posteriori probability. According to example embodiments, a receiver may receive data from a transmitter via a channel. While passing through the channel, an error may occur in the received data due to noise and the like.

The first decoding unit 720 may perform first decoding for the received data based on the calculated likelihood value to generate first decoded data. The first decoded data may refer to data in which the error is partially corrected in the received data. However, the first decoded data may still include an uncorrected error.

The data separator 730 may separate the first decoded data into the plurality of sub-data blocks.

The second decoding unit 740 may perform second decoding for the plurality of sub-data blocks to generate a plurality of second decoded data. According to example embodiments, the second decoding unit 740 may include a plurality of decoders 741, 742, and 743 that may perform second decoding for the plurality of sub-data blocks.

The second decoding unit 740 may perform second decoding for the plurality of sub-data blocks to thereby correct the uncorrected error in the first decoding process. However, the error may still remain in each of the sub-data blocks.

The decoding determination unit 760 may determine whether to perform iterative decoding for the received data based on the second decoded data.

According to example embodiments, the error rate calculator 750 may calculate the error rate of the second decoded data based on whether the error occurs in the second decoded data, or the error rate of the second decoded data. The decoding determination unit 760 may compare the error rate of the second decoded data with a predetermined threshold rate. When the error rate of the second decoded data is less than the threshold rate, the decoding determination unit 760 may determine to not perform iterative decoding for the received data. Conversely, when the error rate of the second decoded data is greater than or equal to the threshold rate, the decoding determination unit 760 may determine to perform iterative decoding for the received data. According to other example embodiments, it is possible to calculate stopping criteria of an iterative decoder based on the calculated likelihood value and thereby determine whether to perform iterative decoding.

According to example embodiments, the data combiner 749 may combine a plurality of second decoded data, generated by the plurality of decoders 741, 742, and 743, to thereby generate a decoded data stream. The error rate calculator 750 may determine whether an error occurs in the decoded data stream, or may calculate an error rate with respect to the decoded data stream.

When the decoding determination unit 760 determines to perform iterative decoding for the received data, the likelihood value calculator 710 may calculate the likelihood value of the received data based on the second decoded data. According to example embodiments, the likelihood value calculator 710 may calculate a likelihood value of each of the second decoded data and combine the calculated likelihood values to thereby calculate the likelihood value of the received data. The likelihood value calculator 710 may combine the likelihood values of the second decoded data based on whether the error occurs in the second decoded data. The likelihood value calculator 710 may assign a higher weight to the likelihood value of the second decoded data where the error does not occur, whereas the likelihood value calculator 710 may assign a lower weight to the likelihood value of the second decoded data where the error occurs. Through this, it is possible to combine the likelihood values of the second decoded data.

In the case of the likelihood value of the second decoded data that is combined based on whether the error occurs in the second decoded data, a portion of the second decoded data where the error does not occur may be greater than a portion of second decoded data where the error occurs. The likelihood value may be a more accurate likelihood value for decoding the received data. Accordingly, when the received data is re-decoded based on the combined likelihood value, it may be possible to correct even an error of the received data that is not corrected in the initial decoding process.

According to example embodiments, the likelihood value calculator 710 may update the likelihood value of the received data based on the likelihood value that is combined based on whether the error occurs in the second decoded data. The first decoding unit 720 may perform first decoding for the received data based on the updated likelihood value.

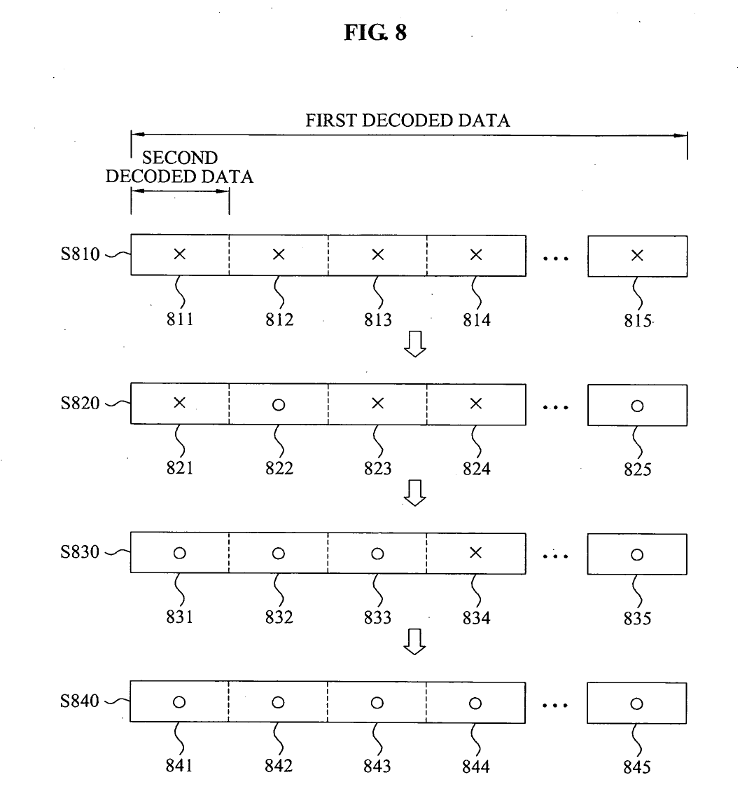

FIG. 8 illustrates an example of performing iterative decoding for received data to thereby reduce an error in a plurality of second decoded data according to example embodiments. Hereinafter, correcting of the error in the received data according to iterative decoding for the received data will be described in detail with reference to FIG 8.

In an initial decoding operation S810, a concatenated code decoding-apparatus may separate first decoded data into a plurality of second decoded data 811, 812, 813, 814, and 815.

In the initial decoding operation S810, whether the error occurred in second decoded data may be determined. When the error occurred in the second decoded data, the error may be partially corrected in the second decoded data.

In the initial decoding operation S810, whether to perform iterative decoding for the received data may be determined based on error-corrected second decoded data. When it is determined to perform iterative decoding for the received data, the concatenated code decoding apparatus may update a likelihood value based on the calculated second decoded data and re-decode the received data based on the updated likelihood value in a second decoding operation S820.

In the second decoding operation S820, the concatenated code decoding apparatus may perform concatenated code decoding for received data. As shown in FIG. 8, whether the error occurred in second decoded data 821, 822, 823, 824, and 825 is already known.

In a third decoding operation S830, errors that occurred in two second decoded data 821 and 823 among the second decoded data 821, 823 and 824 where the error occurred in the second decoding operation S820 are corrected. Accordingly, in the third decoding operation S830, second decoded data 831, 832, 833, and 835 are error-corrected.

In a fourth decoding operation S840, the error of the second decoded data 834 may be corrected and thus the error may be corrected in all the second decoded data 841, 842, 843, 844, and 845.

The concatenated code decoding method according to example embodiments may be recorded in computer-readable media including program instructions to implement various operations embodied by a computer. The media may also include, alone or in combination with the program instructions, data files, data structures, and the like. The media and program instructions may be those specially designed and constructed for the purposes of example embodiments, or they may be of the kind well-known and available to those having skill in the computer software arts. Examples of computer-readable media include magnetic media, for example hard disks, floppy disks, and magnetic tape; optical media, for example CD ROM disks and DVD; magneto-optical media, for example optical disks; and hardware devices that are specially configured to store and perform program instructions, such as read-only memory (ROM), random access memory (RAM), flash memory, and the like. Examples of program instructions include both machine code, for example produced by a compiler, and files containing higher level code that may be executed by the computer using an interpreter. The described hardware devices may be configured to act as one or more software modules in order to perform the operations of example embodiments.

Example embodiments having thus been described, it will be obvious that the same may be varied in many ways. Such variations are not to be regarded as a departure from the intended spirit and scope of example embodiments, and all such modifications as would be obvious to one skilled in the art are intended to be included within the scope of the following claims.

What is claimed is:

1. A method of decoding a concatenated code, comprising:
calculating a likelihood value of concatenated encoded received data;
performing first decoding on the received data based on the calculated likelihood value to generate first decoded data;
performing second decoding on the first decoded data to generate second decoded data; and
determining whether to perform iterative decoding based on the second decoded data.

2. The method of claim 1, further comprising:
updating the likelihood value based on the second decoded data,
wherein generating the first decoded data includes performing first decoding on the received data based on the updated likelihood value to re-generate the first decoded data.

3. The method of claim 2, further comprising:
calculating an error rate of the second decoded data,
wherein updating the likelihood value includes updating the likelihood value based on an error rate.

4. The method of claim 2, further comprising:
updating a number of updates for the likelihood value; and
comparing the updated number of updates for the likelihood value with a predetermined threshold number,
wherein whether to perform iterative decoding is determined based on the result of the comparison.

5. The method of claim 1, further comprising:
calculating an error rate of the second decoded data; and
comparing the error rate with a predetermined threshold rate,
wherein whether to perform the iterative decoding is determined based on the result of the comparison.

6. The method of claim 1, wherein the likelihood value includes at leas tone of a likelihood ratio, a log likelihood ratio (LLR), a probability value, and a posteriori probability.

7. A method of decoding a concatenated code, comprising:
performing first decoding for concatenated encoded received data to generate first decoded data;
separating the first decoded data into a plurality of sub-data blocks; and
performing second decoding for each of the separated sub-data blocks to generate a plurality of second decoded data.

8. The method of claim 7, wherein generating the first decoded data includes performing the first decoding according to an iterative decoding scheme.

9. The method of claim 7, wherein generating the second decoded data includes performing the second decoding according to at least one of a Viterbi decoding scheme, a turbo decoding scheme, a Trellis-Coded Modulation (TCM) decoding scheme, a BCM (Block-Coded Modulation) decoding scheme, a Low-Density Parity-Check codes (LDPC) decoding scheme, a Hamming decoding scheme, a Reed-Solomon (RS) decoding scheme, and a Bose-Chadhuri-Hocquenghem (BCH) decoding scheme.

10. A computer-readable recording medium storing a program for implementing the method of claim 1.

11. An apparatus for decoding a concatenated code, comprising:
a likelihood value calculator configured to calculate a likelihood value of concatenated encoded received data;
a first decoding unit configured to perform first decoding on the received data based on the calculated likelihood value to generate first decoded data;
a second decoding unit configured to perform second decoding on the first decoded data to generate second decoded data; and
a decoding determination unit configured to generate a determination result indicating whether to perform iterative decoding based on the second decoded data.

12. The apparatus of claim 11, wherein:
the likelihood value calculator is configured to update the likelihood value based on the second decoded data depending on the determination result generated by the decoding determination unit, and
the first decoding unit is configured to perform the first decoding for the received data based on the updated likelihood value to re-generate the first decoded data.

13. The apparatus of claim 12, further comprising:
an error rate calculator configured to calculate an error rate of the second decoded data,
wherein the likelihood value calculator is configured to update the likelihood value based on the error rate.

14. The apparatus of claim 12, wherein:
the likelihood value calculator is configured to update a number of updates for the likelihood value, and
the decoding determination unit is configured to compare the updated number of updates with a predetermined threshold number, and to determine whether to perform the iterative decoding based on a result of the comparison.

15. The apparatus of claim 11, further comprising:
an error rate calculator configured to calculate an error rate of the second decoded data,
wherein the decoding determination unit is configured to compare the error rate with a predetermined threshold rate, and to determine whether to perform the iterative decoding based on the result of the comparison.

16. The apparatus of claim 11, wherein the likelihood value includes at least one of a likelihood ratio, an LLR, a probability value, and a posteriori probability.

17. An apparatus for decoding a concatenated code, comprising:
a first decoding unit configured to perform first decoding for concatenated encoded received data to generate first decoded data;
a data separator configured to separate the first decoded data into a plurality of sub-data blocks; and
a second decoding unit configured to perform second decoding for each of the separated plurality of sub-data blocks to generate a plurality of second decoded data.

18. The apparatus of claim 17, wherein the first decoding unit is configured to perform the first decoding according to an iterative decoding scheme.

19. The apparatus of claim 17, wherein the second decoding unit is configured to perform the second decoding according to at least one of a Viterbi decoding scheme, a turbo decoding scheme, a TCM decoding scheme, a BCM decoding scheme, an LDPC decoding scheme, a Hamming decoding scheme, an RS decoding scheme, and a BCH decoding scheme.
